(19) United States
(12) Patent Application Publication
(10) Pub. No.: US 2006/0099830 A1
(43) Pub. Date: May 11, 2006

(54) Plasma implantation using halogenated dopant species to limit deposition of surface layers

(75) Inventors: Steven R. Walther, Andover, MA (US); Sandeep Mehta, Beverly, MA (US); Jay T. Scheuer, Rowley, MA (US)

Correspondence Address: Mark A. Superko, Esq.;Varian Semiconductor Equipment Associates, Inc., 35 Dory Road, Gloucester, MA, 01930, US

(73) Assignee: Varian Semiconductor Equipment Associates, Inc., Gloucester, MA (US)

(21) Appl. No.: 10/981,831

(22) Filed: Nov. 5, 2004

(51) Int. Cl. C23C 14/00; C23C 16/00; H01L 21/31

(52) U.S. Cl. 438/790; 427/523; 118/723 R

(57) ABSTRACT

Methods and apparatus for plasma implantation of a workpiece, such as a semiconductor wafer, are provided. A method includes introducing into a plasma doping chamber a dopant gas selected from the group consisting of PF₃, AsF₃, AsF₅ and mixtures thereof, forming in the plasma doping chamber a plasma containing ions of the dopant gas, the plasma having a plasma sheath at or near a surface of the workpiece, and accelerating the dopant gas ions across the plasma sheath toward the workpiece, wherein the dopant gas ions are implanted into the workpiece. The selected dopant gas limits deposition of neutral particles on the workpiece.

### FIELD OF THE INVENTION

This invention relates to plasma doping systems used for ion implantation of workpieces, such as semiconductor wafers, and, more particularly, to methods and apparatus for limiting deposition of surface layers on semiconductor wafers during plasma implantation.

### BACKGROUND OF THE INVENTION

Plasma doping systems have been studied for forming shallow junctions in semiconductor wafers and for other applications requiring high current, relatively low energy ions. In a plasma doping system, a semiconductor wafer is placed on a conductive platen, which functions as a cathode and is located in a plasma doping chamber. An ionizable doping gas is introduced into the chamber, and a voltage pulse is applied between the platen and an anode or the chamber walls, causing formation of a plasma containing ions of the dopant gas. The plasma has a plasma sheath in the vicinity of the wafer. The applied pulse causes ions in the plasma to be accelerated across the plasma sheath and to be implanted into the wafer. The depth of implantation is related to the voltage applied between the wafer and the anode. Very low implant energies can be achieved. Plasma doping systems are described, for example, in U.S. Pat. No. 5,354,381 issued Oct. 11, 1994 to Sheng; U.S. Pat. No. 6,020,592 issued Feb. 1, 2000 to Liebert, et al.; and U.S. Pat. No. 6,182,604 issued Feb. 6, 2001 to Goeckner, et al.

In the plasma doping systems described above, the applied voltage pulse generates a plasma and accelerates positive ions from the plasma toward the wafer. In other types of plasma systems, a continuous plasma is produced, for example, by inductively-coupled RF power from an antenna located internal or external to the plasma doping chamber. The antenna is connected to an RF power supply. At intervals, voltage pulses are applied between the platen and the anode, causing ions in the plasma to be accelerated toward the wafer.

Dopant gas species used for plasma implantation may decompose or dissociate during the implant process into atomic or molecular fragments which may be deposited on the surface of the wafer. Atomic or molecular fragments that result from dissociation of dopant gas molecules are referred to herein as “neutral particles”. Examples of dopant gas species which dissociate during the implant process include AsH₃, PH₃ and B₂H₆. For example, arsine gas (AsH₃) may dissociate into As, AsH and AsH₂, which may be deposited on the surface of the wafer being implanted. These deposited surface layers can cause a number of problems, including dose nonrepeatability, poor dose uniformity and dose measurement problems. In particular, the neutral particles that form the deposited surface layers are not measured by the dose measurement system. Further, the depth profile of the dopant is altered by the deposited surface layer itself and by its effect on implanted ions. In addition, the deposited surface layers can cause contamination of other equipment, such as annealers, when the wafers are subsequently processed in such equipment.

A method for limiting the formation of a deposited surface layer on a workpiece during plasma implantation is disclosed in International Publication No. WO 2004/013371 A2, published Feb. 12, 2004. A dopant gas and a dilution gas are introduced into a plasma doping chamber for ionization. The dopant gas ions are implanted into the workpiece, and the dilution gas ions remove a deposited surface layer from the workpiece. In another approach, the substrate is heated to promote evaporation of the deposited material. These approaches, while generally satisfactory, increase the cost and complexity of the plasma implantation process.

Accordingly, there is a need for improved methods and apparatus for limiting formation of deposited surface layers during plasma implantation.

### SUMMARY OF THE INVENTION

According to a first aspect of the invention, a method is provided for plasma implantation of a workpiece. The method comprises introducing into a plasma doping chamber a dopant gas selected from the group consisting of PF₃, AsF₃, AsF₅ and mixtures thereof, forming in the plasma doping chamber a plasma containing ions of the dopant gas, the plasma having a plasma sheath at or near a surface of the workpiece, and accelerating the dopant gas ions across the plasma sheath toward the workpiece, wherein the dopant gas ions are implanted into the workpiece.

According to a second aspect of the invention, a method is provided for plasma implantation of a workpiece. The method comprises introducing into a plasma doping chamber a dopant gas selected to limit deposition of neutral particles on the workpiece, forming in the plasma doping chamber a plasma containing ions of the dopant gas, the plasma having a plasma sheath at or near a surface of the workpiece, and accelerating the dopant gas ions across the plasma sheath toward the workpiece, wherein the dopant gas ions are implanted into the workpiece.

According to a third aspect of the invention, a method is provided for plasma implantation of a substrate. The method comprises selecting a dopant gas to limit deposition of neutral particles of the dopant gas on the substrate, introducing the selected dopant gas into a plasma doping chamber, forming in the plasma doping chamber a plasma containing ions of the dopant gas, the plasma having a plasma sheath at or near a surface of the workpiece, and accelerating the dopant gas ions across the plasma sheath toward the substrate, wherein the dopant gas ions are implanted into the substrate.

According to a fourth aspect of the invention, plasma doping apparatus comprises a plasma doping chamber, a platen located in the plasma doping chamber for supporting a workpiece, a process gas source coupled to the plasma doping chamber for introducing into the plasma doping chamber a dopant gas selected from the group consisting of PF₃, AsF₃, AsF₅ and mixtures thereof, a plasma source coupled to the plasma doping chamber for producing a plasma containing ions of the dopant gas, and a pulse source for accelerating the dopant gas ions from the plasma toward the workpiece, wherein the dopant gas ions are implanted into the workpiece.

According to a fifth aspect of the invention, plasma doping apparatus comprises a plasma doping chamber, a platen located in said plasma doping chamber for supporting a workpiece, an anode spaced from said platen in said plasma doping chamber, a process gas source coupled to said plasma doping chamber for introducing into said plasma doping chamber a dopant gas selected from the group consisting of PF₃, AsF₃, AsF₅ and mixtures thereof, wherein a plasma containing ions of the dopant gas is produced in a plasma discharge region between said anode and said platen, and a pulse source for applying pulses between said platen and said anode for accelerating the dopant gas ions from the plasma toward the workpiece, wherein the dopant gas ions are implanted into the workpiece.

### BRIEF DESCRIPTION OF THE DRAWINGS

For a better understanding of the present invention, reference is made to the accompanying drawings, which are incorporated herein by reference and in which:

FIG. 1 is a simplified schematic block diagram of a plasma doping system; and

FIG. 2 is a graph of SIMS dose v. nominal dose for PLAD implants with different species.

### DETAILED DESCRIPTION

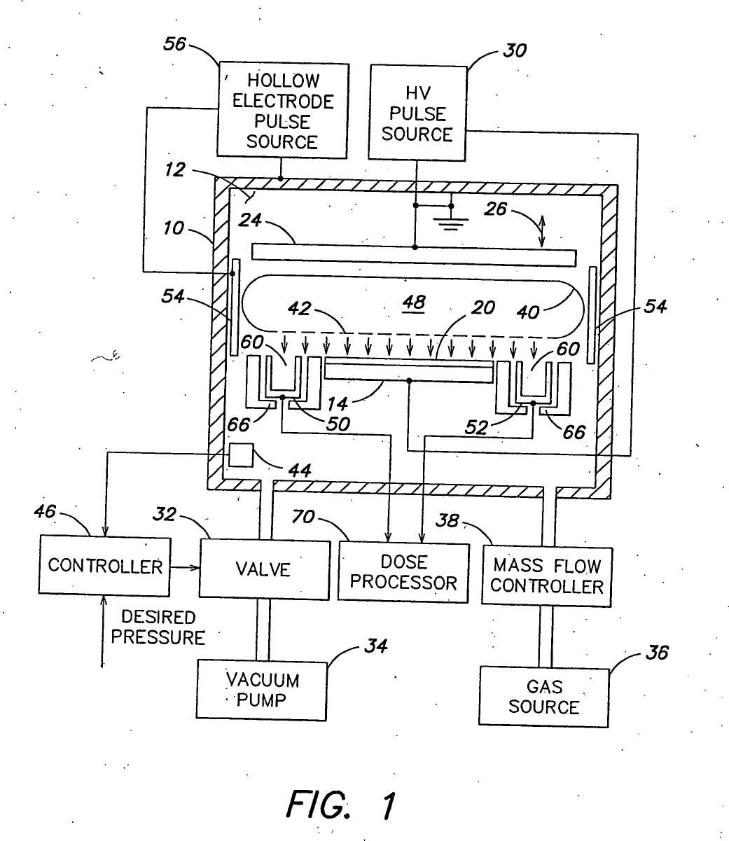

An example of a plasma ion implantation system suitable for implementation of the present invention is shown schematically in FIG. 1. A process chamber 10 defines an enclosed volume 12. A platen 14 positioned within chamber 10 provides a surface for holding a substrate, such as a semiconductor wafer 20. The wafer 20 may, for example, be clamped at its periphery to a flat surface of platen 14 or may be electrostatically clamped. In one embodiment, the platen has an electrically conductive surface for supporting wafer 20. In another embodiment, the platen includes conductive pins (not shown) for connection to wafer 20. In addition, platen 14 may be equipped with a heating/cooling system to control wafer/substrate temperature.

An anode 24 is positioned within chamber 10 in spaced relation to platen 14. Anode 24 may be movable in a direction, indicated by arrow 26, perpendicular to platen 14. The anode is typically connected to electrically conductive walls of chamber 10, both of which may be connected to ground. In another embodiment, platen 14 is connected to ground, and anode 24 is pulsed to a negative voltage. In further embodiments, both anode 24 and platen 14 may be biased with respect to ground.

The wafer 20 (via platen 14) and the anode 24 are connected to a high voltage pulse source 30, so that wafer 20 functions as a cathode. The pulse source 30 typically provides pulses in a range of about 20 to 20,000 volts in amplitude, about 1 to 200 microseconds in duration and a pulse repetition rate of about 100 Hz to 20 kHz. It will be understood that these pulse parameter values are given by way of example only and that other values may be utilized within the scope of the invention.

The enclosed volume 12 of chamber 10 is coupled through a controllable valve 32 to a vacuum pump 34. A process gas source 36 is coupled through a mass flow controller 38 to chamber 10. A pressure sensor 44 located within chamber 10 provides a signal indicative of chamber pressure to a controller 46. The controller 46 compares the sensed chamber pressure with a desired pressure input and provides a control signal to valve 32 or mass flow controller 38. The control signal controls valve 32 or mass flow controller 38 so as to minimize the difference between the chamber pressure and the desired pressure. Vacuum pump 34, valve 32, mass flow controller 38, pressure sensor 44 and controller 46 constitute a closed loop pressure control system. The pressure is typically controlled in a range of about 1 millitorr to about 500 millitorr, but is not limited to this range. Gas source 36 supplies an ionizable gas containing a desired dopant for implantation into the workpiece. Mass flow controller 38 regulates the rate at which gas is supplied to chamber 10. The configuration shown in FIG. 1 provides a continuous flow of process gas at a desired flow rate and constant pressure. The pressure and gas flow rate are preferably regulated to provide repeatable results. In another embodiment, the gas flow may be regulated using a valve controlled by controller 46 while valve 32 is kept at a fixed position. Such an arrangement is referred to as upstream pressure control. Other configurations for regulating gas pressure may be utilized.

The plasma ion implantation system may include a hollow cathode 54 connected to a hollow cathode pulse source 56. In one embodiment, the hollow cathode 54 comprises a conductive hollow cylinder that surrounds the space between anode 24 and platen 14. The hollow cathode may be utilized in applications which require very low ion energies. In particular, hollow cathode pulse source 56 provides a pulse voltage that is sufficient to form a plasma within chamber 12, and pulse source 30 establishes a desired implant voltage. Additional details regarding the use of a hollow cathode are provided in the aforementioned U.S. Pat. No. 6,182,604, which is hereby incorporated by reference.

One or more Faraday cups may be positioned adjacent to platen 14 for measuring the ion dose implanted into wafer 20. In the embodiment of FIG. 1, Faraday cups 50, 52, etc. are equally spaced around the periphery of wafer 20. Each Faraday cup comprises a conductive enclosure having an entrance 60 facing plasma 40. Each Faraday cup is preferably positioned as close as is practical to wafer 20 and intercepts a sample of the positive ions accelerated from plasma 40 toward platen 14. In another embodiment, an annular Faraday cup is positioned around wafer 20 and platen 14.

The Faraday cups are electrically connected to a dose processor 70 or other dose monitoring circuit. Positive ions entering each Faraday cup through entrance 60 produce in the electrical circuit connected to the Faraday cup a current that is representative of ion current. The dose processor 70 may process the electrical current to determine ion dose.

The plasma ion implantation system may include a guard ring 66 that surrounds platen 14. The guard ring 66 may be biased to improve the uniformity of implanted ion distribution near the edge of wafer 20. The Faraday cups 50, 52 may be positioned within guard ring 66 near the periphery of wafer 20 and platen 14.

The plasma ion implantation system may include additional components, depending on the configuration of the system. The system typically includes a process control system (not shown) which controls and monitors the components of the plasma ion implantation system to implement a desired implant process. Systems which utilize continuous or pulsed RF energy include an RF source coupled to an antenna or an induction coil. The system may include magnetic elements which provide magnetic fields that confine electrons and control plasma density and spatial distribution. The use of magnetic elements in plasma ion implantation systems is described, for example, in WO 03/049142, published 12 Jun. 2003, which is hereby incorporated by reference.

In operation, wafer 20 is positioned on platen 14. The pressure control system, mass flow controller 38 and gas source 36 produce the desired pressure and gas flow rate within chamber 10. By way of example, the chamber 10 may operate with BF₃ gas at a pressure of 10 millitorr. The pulse source 30 applies a series of high voltage pulses to wafer 20, causing formation of plasma 40 in a plasma discharge region 48 between wafer 20 and anode 24. As known in the art, plasma 40 contains positive ions of the ionizable gas from gas source 36. Plasma 40 includes a plasma sheath 42 in the vicinity, typically at the surface, of wafer 20. The electric field that is present between anode 24 and platen 14 during the high voltage pulse accelerates positive ions from plasma 40 across plasma sheath 42 toward platen 14. The accelerated ions are implanted into wafer 20 to form regions of impurity material. The pulse voltage is selected to implant the positive ions to a desired depth in wafer 20. The number of pulses and the pulse duration are selected to provide a desired dose of impurity material in wafer 20. The current per pulse is a function of pulse voltage, pulse width, pulse frequency, gas pressure and species and any variable position of the electrodes. For example, the cathode-to-anode spacing may be adjusted for different voltages.

As noted above, dopant gas species typically used for plasma implantation may dissociate into neutral particles during the implant process and form deposited surface layers on wafer 20. Examples of dopant gas species which form deposited surface layers include AsH₃ (arsine), PH₃ (phosphine) and B₂H₆. For example, arsine gas may dissociate into As, AsH and AsH₂, which may be deposited on the surface of wafer 20. These deposited surface layers cause dose non-repeatability, poor dose uniformity and metrology problems.

In accordance with an aspect of the invention, dopant species are selected which exhibit improved ionization efficiency and reduced dissociation to form neutral particles in comparison with conventional dopant gas species, such as the hydrides of dopant materials including PH₃ and AsH₃. As a result of more efficient ionization, a larger percentage of the dopant gas is ionized and implanted into the wafer and a lower percentage of the dopant gas is deposited on the wafer surface in the form of neutral particles. Examples of suitable dopant gas species include halogen-containing dopant gas species. The halogen-containing dopant gas promotes chemical etching of the implanted surface, which removes dopant material deposited on the surface of the wafer. For example, fluorides and chlorides of the dopant materials may be utilized. Specific examples include PF₃, AsF₃, and AsF_{5.}

Species such as PF₃, AsF₃, and AsF₅ may be used for plasma implantation in a manner similar to prior art dopant species such as AsH₃ and PH₃. In order to obtain an equivalent implantation depth, the implant energy is adjusted to compensate for the mass of the dopant gas species. As known in the art, a dopant species with a higher mass requires higher energy in order to obtain the same implant depth in the semiconductor wafer. The pressure levels utilized for plasma implantation with dopant gas species according to embodiments of the invention are substantially similar to those used in prior art plasma implantation systems. As noted above, the pressure is typically controlled in a range of about 1 millitorr to about 500 millitorr.

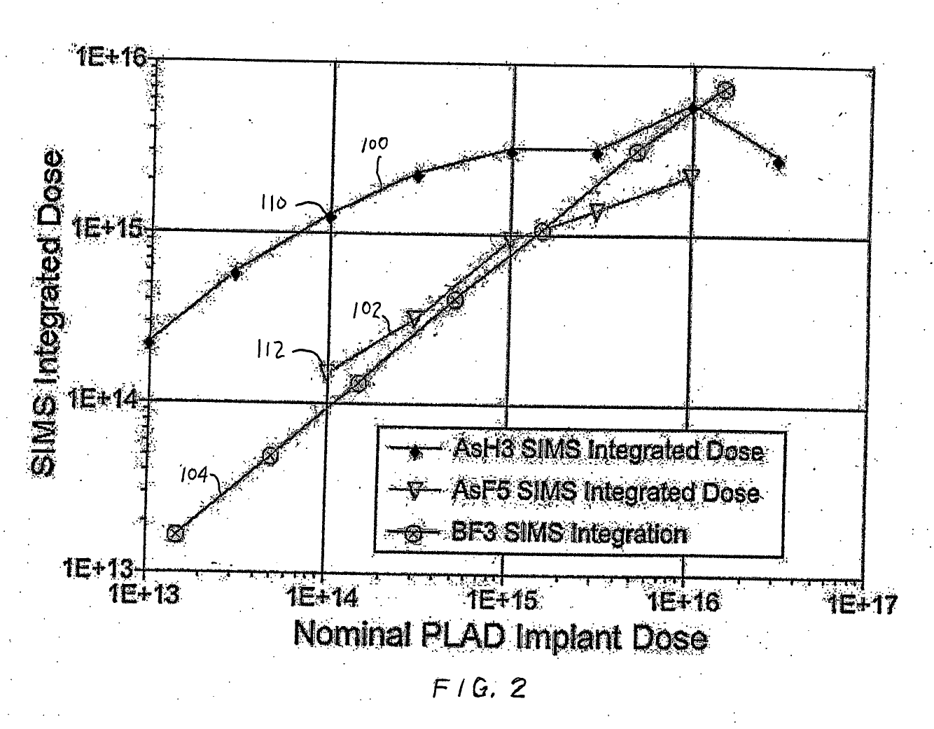

A comparison of results obtained using embodiments of the invention and results obtained using prior art dopant gas species is shown in FIG. 2. In FIG. 2, SIMS (Secondary Ion Mass Spectrometry) integrated dose is plotted as a function of nominal PLAD (Plasma Doping) implant dose. The nominal implant dose is the implant dose measured by the Faraday system of the plasma implantation system, such as Faraday cups 50 and 52 shown in FIG. 1 and described above. The SIMS measurement is a well-known technique for determining dose implanted into the wafer by analysis of the wafer. The nominal implant dose represents a measurement of charged particles, whereas the SIMS measurement represents a measurement of charged particles and neutral particles, including deposited surface layers. In a system with no deposition of neutral particles, the two measurements should yield equal values.

In FIG. 2, curve 100 represents AsH₃ integrated dose, curve 102 represents a AsF₅ integrated dose, and curve 104 represents BF₃ integrated dose. Curve 104 is shown for reference. The units on each axis of FIG. 2 are atoms per cubic centimeter (cm³). Thus for example, the notation “1E +14” refers to a dose of 1×10¹⁴ atoms per cm³. A logarithmic scale is used on both axes of FIG. 2.

Referring to curve 104, which represents BF₃, at a nominal implant dose of 1E+14, the SIMS integrated dose is slightly less than 1E+14. The close agreement between the nominal implant dose and the SIMS integrated dose indicates little or no deposition on the surface of the wafer. By contrast, for AsH₃ (curve 100) at a nominal implant dose of 1E+14, the SIMS integrated dose exceeds 1E+15, as indicated at point 110 on curve 100. This difference indicates that the neutral particle deposition on the surface of the wafer exceeds the implanted ion dose by a factor of about 10. In the case of AsF₅, according to an embodiment of the invention, for a nominal implant dose of 1E+14, the SIMS integrated dose is on the order of 1.3 E+14, as indicated by point 112 on curve 102. Thus, curve 102 is indicative of relatively low deposition of neutral particles on the wafer surface when the dopant gas species is AsF_{5.}

As noted above, formation of a deposited surface layer on a workpiece may be limited by utilizing a dopant gas and a dilution gas. Dopant gas ions are implanted into the wafer and dilution gas ions remove a deposited surface layer from the wafer. The dopant gas species described above may be utilized with a dilution gas to limit formation of deposited surface layers during plasma ion implantation.

The atomic masses of the dopant gas and the dilution gas may be similar to achieve efficient removal of the deposited surface layers. The ratio of the dilution gas to the dopant gas is selected to remove the deposited surface layers as they are formed. For example, an inert dilution gas, such as krypton or xenon, may be utilized. In other examples, dilution gases such as argon or neon may be utilized. In further examples, the dilution gas may include a chemically active component, such as a halogen and more particularly, may include fluorine or chlorine. Additional details regarding the use of a dilution gas with a dopant gas are disclosed in International Publication No. WO/2004/013371 A2, which is hereby incorporated by reference.

Having described several embodiments and an example of the invention in detail, various modifications and improvements will readily occur to those skilled in the art. Such modifications and improvements are intended to be within the spirit and the scope of the invention. Furthermore, those skilled in the art would readily appreciate that all parameters listed herein are meant to be exemplary and that actual parameters will depend upon the specific application for which the system of the present invention is used. Accordingly, the foregoing description is by way of example only and is not intended as limiting. The invention is limited only as defined by the following claims and their equivalents.

What is claimed is:

1. A method for plasma implantation of a workpiece, comprising:
introducing into a plasma doping chamber a dopant gas selected from the group consisting of PF₃, AsF₃, AsF₅ and mixtures thereof;
forming in the plasma doping chamber a plasma containing ions of the dopant gas, the plasma having a plasma sheath at or near a surface of the workpiece; and
accelerating the dopant gas ions across the plasma sheath toward the workpiece, wherein the dopant gas ions are implanted into the workpiece.

2. A method as defined in claim 1, wherein introducing a dopant gas comprises introducing PF_{3.}

3. A method as defined in claim 1, wherein introducing a dopant gas comprises introducing AsF_{3.}

4. A method as defined in claim 1, wherein introducing a dopant gas comprises introducing AsF_{5.}

5. A method as defined in claim 1, further comprising placing a semi-conductor wafer in the plasma doping chamber for plasma implantation with the dopant gas ions.

6. A method as defined in claim 1, wherein introducing a dopant gas further comprises introducing a dilution gas selected to remove a deposited surface layer from the workpiece.

7. A method for plasma implantation of a workpiece, comprising:
introducing into a plasma doping chamber a dopant gas selected to limit deposition of neutral particles on the workpiece;
forming in the plasma doping chamber a plasma containing ions of the dopant gas, the plasma having a sheath at or near a surface of the workpiece; and
accelerating the dopant gas ions across the plasma sheath toward the workpiece, wherein the dopant gas ions are implanted into the workpiece.

8. A method as defined in claim 7, wherein introducing a dopant gas comprises introducing a halogen-containing species of phosphorous or arsenic.

9. A method as defined in claim 7, wherein introducing a dopant gas comprises introducing a dopant gas selected from the group consisting of PF₃, AsF₃, AsF₅ and mixtures thereof.

10. A method as defined in claim 7, further comprising placing a semiconductor wafer in the plasma doping chamber for plasma implantation with dopant gas ions.

11. A method as defined in claim 7, wherein introducing a dopant gas further comprises introducing a dilution gas selected to remove a deposited surface layer from the workpiece.

12. A method for plasma implantation of a substrate, comprising;
selecting a dopant gas to limit deposition of neutralized particles on the substrate;
introducing the selected dopant gas into a plasma doping chamber;
forming in the plasma doping chamber a plasma containing ions of the dopant gas, the plasma having a plasma sheath at or near a surface of the workpiece; and
accelerating the dopant gas ions across the plasma sheath toward the substrate, wherein the dopant gas ions are implanted into the substrate.

13. A method as defined in claim 12, wherein selecting a dopant gas comprises selecting a halogen-containing species of phosphorous or arsenic.

14. A method as defined in claim 12, wherein selecting a dopant gas comprises selecting a dopant gas from the group consisting of PF₃, AsF₃, and AsF₅ and mixtures thereof.

15. A method as defined in claim 12, further comprising placing a semiconductor wafer in the plasma doping chamber for plasma implantation with the dopant gas ions.

16. A method as defined in claim 12, wherein introducing the selected dopant gas further comprises introducing a dilution gas selected to remove a deposited surface layer from the workpiece.

17. Plasma doping apparatus comprising:
a plasma doping chamber;
a platen located in said plasma doping chamber for supporting a workpiece;
a process gas source coupled to said plasma doping chamber for introducing into said plasma doping chamber a dopant gas selected from the group consisting of PF₃, AsF₃, AsF₅ and mixtures thereof;
a plasma source coupled to said plasma doping chamber for producing a plasma containing ions of the dopant gas; and
a pulse source for accelerating the dopant gas ions from the plasma toward the workpiece, wherein the dopant gas ions are implanted into the workpiece.

18. Plasma doping apparatus comprising:
a plasma doping chamber;
a platen located in said plasma doping chamber for supporting a workpiece;
an anode spaced from said platen in said plasma doping chamber;
a process gas source coupled to said plasma doping chamber for introducing into said plasma doping chamber a dopant gas selected from the group consisting of PF₃, AsF₃, AsF₅ and mixtures thereof, wherein a plasma containing ions of the dopant gas is produced in a plasma discharge region between said anode and said platen; and
a pulse source for applying pulses between said platen and said anode for accelerating the dopant gas ions from the plasma toward the workpiece, wherein the dopant gas ions are implanted into the workpiece.
